(19) United States
(12) Patent Application Publication
(10) Pub. No.: US 2016/0225994 A1
(43) Pub. Date: Aug. 4, 2016

(54) ORGANIC THIN FILM TRANSISTOR AND METHOD FOR MANUFACTURING THE SAME

(71) Applicant: Industry Academic Cooperation Foundation, Hallym University, Chuncheon (KR)

(72) Inventors: Jae Hoon Park, Chuncheon-si (KR); Seo Yeon Lee, Namyangju-si (KR)

(21) Appl. No.: 14/962,396

(22) Filed: Dec. 8, 2015

(30) Foreign Application Priority Data
Jan. 29, 2015 (KR) 10-2015-0014103

(51) Int. Cl. H01L 51/00; H01L 51/05; H01L 51/10

(52) U.S. Cl. CPC H01L 51/0007; H01L 51/0028; H01L 51/0023; H01L 51/102; H01L 51/0558; H01L 51/105; H01L 51/0545; H01L 51/0541

(57) ABSTRACT

Provided is a method for forming a pattern of an organic thin film semiconductor element. The method for forming a pattern of an organic thin film semiconductor element includes: preparing a mold structure having a groove; positioning the mold structure on an upper part of a substrate to enable the groove and the substrate to form a pipe; supplying an organic semiconductor material to a surface of the substrate; and hardening the organic semiconductor material.

### CROSS-REFERENCE TO RELATED APPLICATION

This application claims the benefit of Korean Patent Application No. 10-2015-0014103 filed on Jan. 29, 2015, the disclosures of which are incorporated herein by reference.

### TECHNICAL FIELD

The present disclosure relates to an organic thin film transistor and a method for manufacturing the organic thin film transistor.

### BACKGROUND

As modern industrial society evolves into a highly information-oriented society, display devices have become larger and thinner in response to the needs of the market. Since conventional CRT devices cannot sufficiently satisfy the needs, a demand for flat panel display devices represented by PDP (Plasma Display Panel) devices, PALC (Plasma Address Liquid Crystal display panel) devices, LCD (Liquid Crystal Display) devices, and OLED (Organic Light Emitting Diode) devices have been sharply increased.

In a flat panel display device, a thin film transistor (TFT), which is a three-terminal element, is used as a switching element. Further, the flat panel display device is provided with a gate line configured to transfer a scanning signal for controlling the thin film transistor and a data line configured to transfer a signal to be applied to a pixel electrode.

As the thin film transistor, particularly, an organic thin film transistor (OTFT) including a low-molecular or high-molecular organic semiconductor instead of an inorganic semiconductor such as silicon (Si) has been actively studied. For example, a conventional organic thin film transistor is disclosed in Korean Patent Laid-open Publication No. 2004-0012212.

The organic thin film transistor can be formed into fiber or a film due to properties of an organic material and thus has attracted a lot of attention as a core element of a flexible display device. Further, the organic thin film transistor can be manufactured by a solution process such as inkjet printing and thus can be easily applied to large-area flat panel display device which cannot be achieved only by a deposition process.

However, the driving performance of a conventional thin film transistor largely depends on a deviation occurring during a manufacturing process. In particular, a difference in exposure during a process for exposing a photoresist layer causes deviations of a width and a shape of a channel in the thin film transistor. Further, a transfer printing method, in which a low-molecular monocrystal is chemically formed and implanted into an element by a transfer method, needs a separate transfer process, is necessarily subject to an alignment process during the transfer process, and results in poor interface properties. Further, according to a direct printing method of directly printing a desired target, it is difficult to control the crystal orientation and the crystal size of an organic semiconductor.

Accordingly, there has been a demand for a high-quality monocrystalline thin film transistor with excellent charge mobility and excellent current output and a method for easily manufacturing the same.

### SUMMARY

In view of the foregoing, the present disclosure provides a high-quality monocrystalline organic semiconductor thin film with high charge mobility and high current output and a method for manufacturing the same.

Further, the present disclosure provides a method for manufacturing a monocrystalline organic thin film transistor by applying a solution process which is capable of simplifying a process to improve a speed and saving an amount of a material used.

Furthermore, the present disclosure provides a method for manufacturing an organic thin film transistor having a micro pattern at a higher speed with more ease.

However, problems to be solved by the present exemplary embodiments are not limited to the above-described problems, and other problems may be present.

According to an exemplary embodiment, there is provided a method for forming a pattern of an organic thin film semiconductor element, including: preparing a mold structure having a groove; positioning the mold structure on an upper part of a substrate to enable the groove and the substrate to form a pipe; supplying an organic semiconductor material to a surface of the substrate; and hardening the organic semiconductor material, in which the organic semiconductor material may flow in the pipe formed by the groove of the mold structure and the substrate.

Further, according to an exemplary embodiment, there is provided a method for manufacturing an organic thin film transistor, including: forming a gate electrode on a substrate; forming an organic semiconductor layer on an upper part of the gate electrode; and forming a source electrode and a drain electrode electrically connected with the organic semiconductor layer. The forming an organic semiconductor layer may include: preparing a mold structure having a groove; positioning the mold structure on an upper part of the substrate to enable the groove and the substrate to form a pipe; supplying an organic semiconductor material to the substrate; and hardening the organic semiconductor material, in which the organic semiconductor material may flow in the pipe formed by the groove of the mold structure and the substrate.

Furthermore, according to an exemplary embodiment, there is provided a method for manufacturing an organic thin film transistor, including: forming a source electrode and a drain electrode on a substrate; forming an organic semiconductor layer to be in contact with the source electrode and the drain electrode; and forming a gate electrode on upper parts of the organic semiconductor layer, the source electrode, and the drain electrode. The forming an organic semiconductor layer may include: preparing a mold structure having a groove; positioning the mold structure on an upper part of the substrate to enable the groove and the substrate to form a pipe; supplying an organic semiconductor material to the substrate; and hardening the organic semiconductor material, in which the organic semiconductor material may flow in the pipe formed by the groove of the mold structure and the substrate.

Moreover, according to an exemplary embodiment, there is provided an organic thin film transistor including: an organic semiconductor layer formed of an organic semiconductor material; a source electrode and a drain electrode positioned to be in contact with the organic semiconductor layer and to face each other; a gate electrode configured to apply an electric field to the organic semiconductor layer; and a gate insulation layer positioned between the gate electrode and the organic semiconductor layer. The organic semiconductor layer may be formed by a method for forming a pattern of a semiconductor element, including: preparing a mold structure having a groove; positioning the mold structure on an upper part of the substrate to enable the groove and the substrate to form a pipe; supplying an organic semiconductor material to a surface of the substrate; and hardening the organic semiconductor material, in which the organic semiconductor material may flow in the pipe formed by the groove of the mold structure and the substrate.

Besides, according to an exemplary embodiment, there is provided an organic thin film transistor including: a gate electrode; an organic semiconductor layer formed on an upper part of the gate electrode; and a source electrode and a drain electrode electrically connected with the organic semiconductor layer. The organic semiconductor layer may be formed by a method for forming a pattern of a semiconductor element, including: preparing a mold structure having a groove; positioning the mold structure on an upper part of the substrate to enable the groove and the substrate to form a pipe; supplying an organic semiconductor material to a surface of the substrate; and hardening the organic semiconductor material, in which the organic semiconductor material may flow in the pipe formed by the groove of the mold structure and the substrate.

According to an exemplary embodiment, it is possible to manufacture a high-quality monocrystalline organic semiconductor thin film with high charge mobility and high current output.

Further, according to exemplary embodiment, it is possible to simplify a process to improve a speed and save an amount of a material used when manufacturing an organic thin film transistor.

Furthermore, according to exemplary embodiment, it is possible to manufacture an organic thin film transistor having a micro pattern at a high speed with ease.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1A and FIG. 1B are conceptual diagrams illustrating a process for forming a pattern of an organic thin film semiconductor element according to an exemplary embodiment of the present disclosure;

FIG. 2 is a conceptual diagram illustrating a process for forming a pattern of an organic thin film semiconductor element according to another exemplary embodiment of the present disclosure;

FIG. 3A and FIG. 3B are conceptual diagrams illustrating a process for forming a pattern of an organic thin film semiconductor element according to yet another exemplary embodiment of the present disclosure;

FIG. 4 is a cross-sectional view of an organic thin film transistor according to an exemplary embodiment of the present disclosure;

FIG. 5 is a cross-sectional view of an organic thin film transistor according to another exemplary embodiment of the present disclosure;

FIG. 6 is a flowchart showing a method for forming a pattern of an organic thin film semiconductor element according to an exemplary embodiment of the present disclosure;

FIG. 7 is a flowchart showing a method for manufacturing an organic thin film transistor according to an exemplary embodiment of the present disclosure; and

FIG. 8 is a flowchart showing a method for manufacturing an organic thin film transistor according to another exemplary embodiment of the present disclosure.

### DETAILED DESCRIPTION

Hereinafter, embodiments of the present disclosure will be described in detail with reference to the accompanying drawings so that the present disclosure may be readily implemented by those skilled in the art. However, it is to be noted that the present disclosure is not limited to the embodiments but can be embodied in various other ways. In drawings, parts irrelevant to the description are omitted for the simplicity of explanation, and like reference numerals denote like parts through the whole document.

Through the whole document, the term “connected to” or “coupled to” that is used to designate a connection or coupling of one element to another element includes both a case that an element is “directly connected or coupled to” another element and a case that an element is “electronically connected or coupled to” another element via still another element.

Through the whole document, the term “on” that is used to designate a position of one element with respect to another element includes both a case that the one element is adjacent to the another element and a case that any other element exists between these two elements.

Further, through the whole document, the term “comprises or includes” and/or “comprising or including” used in the document means that one or more other components, steps, operation and/or existence or addition of elements are not excluded in addition to the described components, steps, operation and/or elements unless context dictates otherwise.

Through the whole document, the term “about or approximately” or “substantially” is intended to have meanings close to numerical values or ranges specified with an allowable error and intended to prevent accurate or absolute numerical values disclosed for understanding of the present disclosure from being illegally or unfairly used by any unconscionable third party. Through the whole document, the term “step of” does not mean “step for”.

Through the whole document, a part of an operation or function described as being carried out by a terminal, apparatus or device may be carried out by a server connected to the terminal, apparatus or device. Likewise, a part of an operation or function described as being carried out by a server may be carried out by a terminal, apparatus or device connected to the server. Hereinafter, exemplary embodiments of the present disclosure will be described in detail with reference to the accompanying drawings.

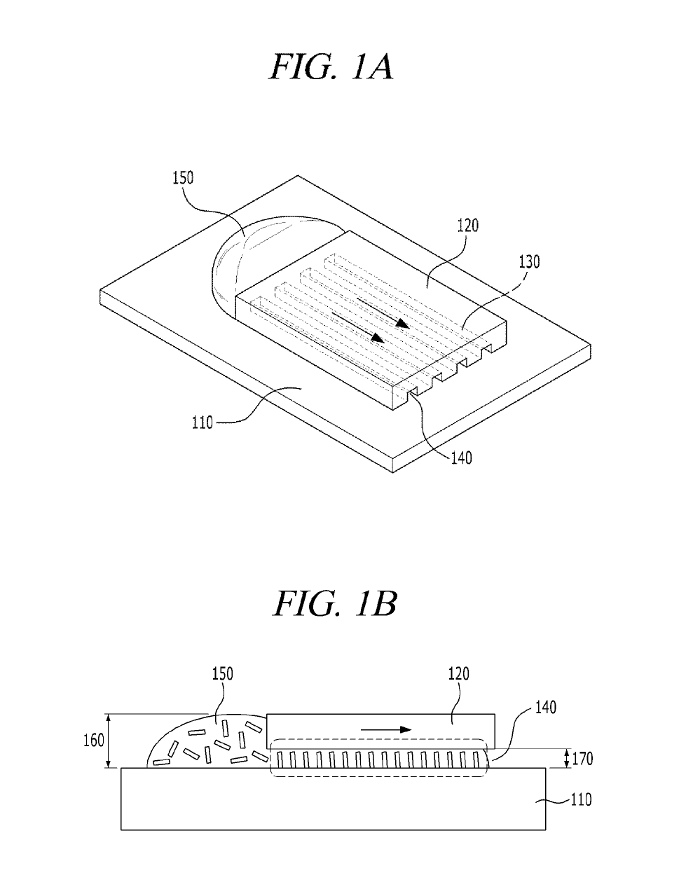

FIG. 1A and FIG. 1B are conceptual diagrams illustrating a process for forming a pattern of an organic thin film semiconductor element according to an exemplary embodiment of the present disclosure.

As illustrated in FIG. 1A and FIG. 1B, a mold structure 120 for forming a micro pattern of a semiconductor element may be positioned on an upper part of a substrate 110. For example, the substrate 110 may include at least any one of a silicon substrate, a glass substrate, a plastic substrate, or a metal substrate. The glass substrate may be formed of silicon oxide, silicon nitride, and the like. Further, the plastic substrate may be formed of an organic insulating material and may be formed of, for example, an organic material selected from the group consisting of polyethersulphone (PES), polyacrylate (PAR), polyetherimide (PEI), polyethylene naphthalate (PEN), polyethylene terephthalate (PET), polyphenylene sulfide (PPS), polyarylate, polyimide, polycarbonate (PC), cellulose triacetate (TAC), and cellulose acetate propionate (CAP), but is not limited thereto. Further, the metal substrate may include one or more members selected from the group consisting of carbon, iron, chromium, manganese, nickel, titanium, molybdenum, stainless steel (SUS), an Invar alloy, a ZInconel alloy, and a Kovar alloy, but is not limited thereto.

The mold structure 120 may be formed into a shape having one or more grooves 130. For example, the mold structure 120 may be formed by a general mold manufacturing process including: molding a resin material and performing an ultraviolet treatment and demolding. Since the mold structure is formed using the flexible material, it is possible to form patterns having various shapes.

For example, a width of the groove 130 may have a size in the range of from several tens of nanometers (nm) to several micrometers (μm), and a height of the groove 130 may have a size of several hundreds of nanometers (nm). Further, a distance between adjacent grooves included in the mold structure 120 may have a size of several hundreds of nanometers (nm).

The mold structure 120 may be positioned on the upper part of the substrate 110 to enable the groove 130 of the mold structure 120 and a top surface of the substrate 110 to form a pipe 140 or a passage. For example, the prepared mold structure 120 may be bonded to the top surface of the substrate 110 with an adhesive to allow a bottom surface of the groove 130 to face the top surface of the substrate 110. A width and a height of the pipe 140 and a distance between adjacent pipes are equal to the above-described width and height of the groove 130 of the mold structure 120 and the above-described distance between the adjacent grooves, respectively.

As such, in a state where the mold structure 120 is positioned on the top surface of the substrate 110, an organic semiconductor material 150 may be supplied to a surface of the substrate 110. The supplied organic semiconductor material 150 may be introduced into the pipe 140 formed by the groove 130 of the mold structure 120 and the substrate 110 and may flow on the top surface of the substrate 110 through the pipe 140. To be more specific, when the organic semiconductor material 150 is supplied to the surface of the substrate 110, a height 160 formed by the organic semiconductor material 150 is greater than a height 170 of the pipe 140. In other words, the organic semiconductor material 150 is introduced into the pipe 140 due to a pressure difference between the inside and the outside of the pipe 140 and then flows on the top surface of the substrate 110 through the pipe 140. A size of the pipe 140 into which the organic semiconductor material 150 is introduced may be determined according to a size and a shape of the groove 130 of the mold structure 120. Accordingly, a pressure difference between the inside and the outside of the pipe 140 may be changed. Therefore, a speed of the organic semiconductor material 150 when flowing in the pipe 140 may be changed. Depending on the speed, a crystal quality, an alignment direction, or a quality factor of organic molecules may be determined. Thus, the performance of the organic thin film semiconductor element or transistor may be determined.

Further, by performing a process for controlling surface energy on the surface of the substrate 110, it is possible to introduce the organic semiconductor material 150 into the pipe 140 and further possible to control a speed of the organic semiconductor material 150 when flowing in the pipe 140. For example, by performing an ultraviolet ozone (UVO) treatment or oxygen plasma treatment to the surface of the substrate 110, it is possible to lower the surface energy on the substrate and introduce the organic semiconductor material 150 into the pipe 140. For example, the ultraviolet ozone (UVO) treatment or oxygen plasma treatment may be selectively performed to a region in contact with the organic semiconductor material 150 on the substrate 110.

As illustrated in FIG. 1B, while the organic semiconductor material 150 is introduced into the pipe 140 and flows in the pipe 140, organic molecules included in the organic semiconductor material 150 may be aligned to have a certain directionality, and, thus, a pattern of a monocrystalline semiconductor element may be formed.

In addition, the organic semiconductor material 150 flowing in the pipe 140 may be hardened. For example, the organic semiconductor material 150 may be hardened by natural drying or annealing. In this way, a liquid (solvent) component included in the organic semiconductor material 150 evaporates. Since the organic semiconductor material 150 is hardened, the organic semiconductor material 150 present within the pipe 140 may be formed as a pattern of the organic thin film semiconductor element along a shape of the pipe 140.

An evaporation rate of the liquid component may vary depending on the kind of the organic semiconductor material 150. Further, a speed of the organic semiconductor material 150 when flowing and proceeding in the pipe 140 may vary depending on the evaporation rate of the liquid component. For example, when the evaporation rate of the liquid component is high, the speed of the organic semiconductor material 150 when flowing and proceeding in the pipe 140 may be increased. Further, a crystal quality or a quality factor of the organic molecules may be determined depending on the speed of the organic semiconductor material 150 when flowing and proceeding in the pipe 140. Thus, the performance of the organic thin film semiconductor element or transistor may be determined.

Further, the performance of the organic thin film semiconductor element or transistor may be determined depending on the surface characteristics of the substrate 110, the kind and characteristics of the organic semiconductor material 150 supplied to the surface of the semiconductor 110, and the degree of interaction between the surface of the substrate 110 and the organic semiconductor material 150. These characteristics and degree of interaction may be adjusted by the above-described surface treatment of the substrate 110.

As the organic semiconductor material 150, any organic semiconductor material may be used as long as it enables formation of a thin film through a solution process. For example, pentacene precursors, polythiopene and its derivatives, polyparaphenylene vinylene and its derivatives, polyfluorene and its derivatives, polythiopene vinylene and its derivatives, a polythiophene-heterocyclic aromatic copolymer and its derivatives, phthalocyanine that includes or does not include a metal and its derivatives, TESADT (triethylsilylethynyl anthradithiophene), BTBT (benzothienobenzothiophene), TTF (tetrathiafulvalene), and the like may be used. Further, two or more of them may be used.

Further, the crystal size and/or crystal orientation of the organic semiconductor material 150 may be determined depending on the kind of the organic semiconductor material 150. For example, by the method for forming a pattern according to an exemplary embodiment of the present disclosure, it is possible to manufacture a high crystalline TIPS-Pn film in which crystals of the organic molecules are aligned in a vertical direction and also possible to manufacture a high crystalline PCBM film in which crystals of the organic molecules are aligned in a horizontal direction. Furthermore, the crystal size and/or crystal orientation of the organic semiconductor material 150 may be controlled depending on a size of the groove 130 of the mold structure 120, i.e., a size of the pipe 140, in addition to the kind of the organic semiconductor material 150.

A width and a height of the pattern of the monocrystalline semiconductor element formed of the organic semiconductor material 150 may be determined depending on the width and the height of the pipe 140. For example, a width of the pattern of the monocrystalline semiconductor element may have a size in the range of from several tens of nanometers (nm) to several micrometers (μm), and a height of the pattern of the monocrystalline semiconductor element may have a size in the range of from several tens of nanometers (nm) to several hundreds of nanometers (nm).

As described above, the organic thin film semiconductor element can be patterned by supplying the organic semiconductor material to the mold structure having a micro- or nano-sized pattern and using capillary phenomenon through the solution process. According to the capillary lithography of the present disclosure, it is not necessary to perform conventional film forming process, photolithography process, transfer process and alignment process. Thus, the process is simplified and a processing rate is improved. Accordingly, a throughput can be improved. Further, since the organic semiconductor material is supplied in an amount suitable for a size of the mold structure, most of the organic semiconductor material supplied for the process is used, thereby increasing the utilization of resources and minimizing wastes generated after the process. Furthermore, according to the capillary lithography of the present disclosure, it is possible to easily form a high crystalline organic semiconductor element with high charge mobility and high current output. Moreover, it is possible to adjust crystallinity and alignment of the organic molecules and a direction of crystal growth by adjusting and modifying a size and a shape of the mold structure and adjusting a pressure difference between the inside and the outside of the pipe and a direction thereof.

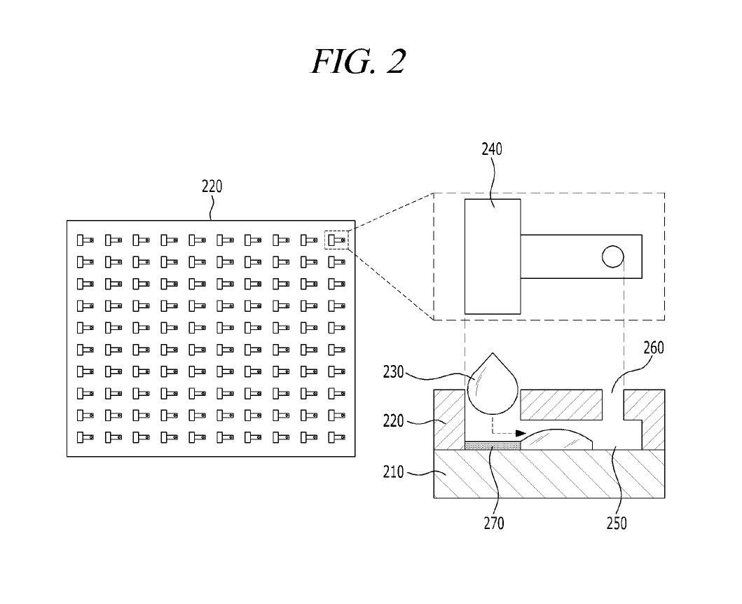

FIG. 2 is a conceptual diagram illustrating a process for forming a pattern of an organic thin film semiconductor element according to another exemplary embodiment of the present disclosure.

As illustrated in FIG. 2, according to an exemplary embodiment of the present disclosure, a mold structure 220 with an array of grooves having the same shape may be positioned on an upper part of a substrate 210. The mold structure 220 is positioned on the upper part of the substrate 210 to enable the grooves of the mold structure 220 and the substrate 210 to form a passage in which an organic semiconductor material 230 flows.

For example, as illustrated in FIG. 2, the grooves of the mold structure 220 may include an inlet part 240 for introducing the organic semiconductor material 230 and a proceeding part 250 for forming a pipe in which the organic semiconductor material 230 flows on a top surface of the substrate. Further, the mold structure 220 may include a hole 260 for inducing and promoting evaporation of a solvent component in the organic semiconductor material 230. A shape of the grooves of the mold structure 220 illustrated in FIG. 2 is just an example and may have other shapes which can form a pipe in which the organic semiconductor material 230 is introduced and flows.

Further, as illustrated in FIG. 2, the ultraviolet ozone (UVO) treatment or oxygen plasma treatment may be selectively performed to a region 270 (for example, a surface of the substrate corresponding to the inlet part 240) in contact with the introduced organic semiconductor material 230 on the substrate 210. As such, by controlling surface energy on the surface 270 of the substrate where the organic semiconductor material 230 is first introduced and condensed, it is possible to introduce the organic semiconductor material 230 into the pipe 250 formed by the grooves of the mold structure 220 and the substrate 210 and induce the organic semiconductor material 230 to flow through the surface of the substrate 210 without overflowing out of the mold structure 220.

In the method for forming a pattern of an organic thin film semiconductor element according to an exemplary embodiment of the present disclosure, a mold structure with a large-area groove array including a large number of grooves is prepared and the mold structure and a substrate are bonded to each other to form a passage in which an organic semiconductor material can flow. By inducing the organic semiconductor material to the passage, a large number of patterns of an organic thin film semiconductor element can be formed rapidly and easily through a solution process based on capillary phenomenon.

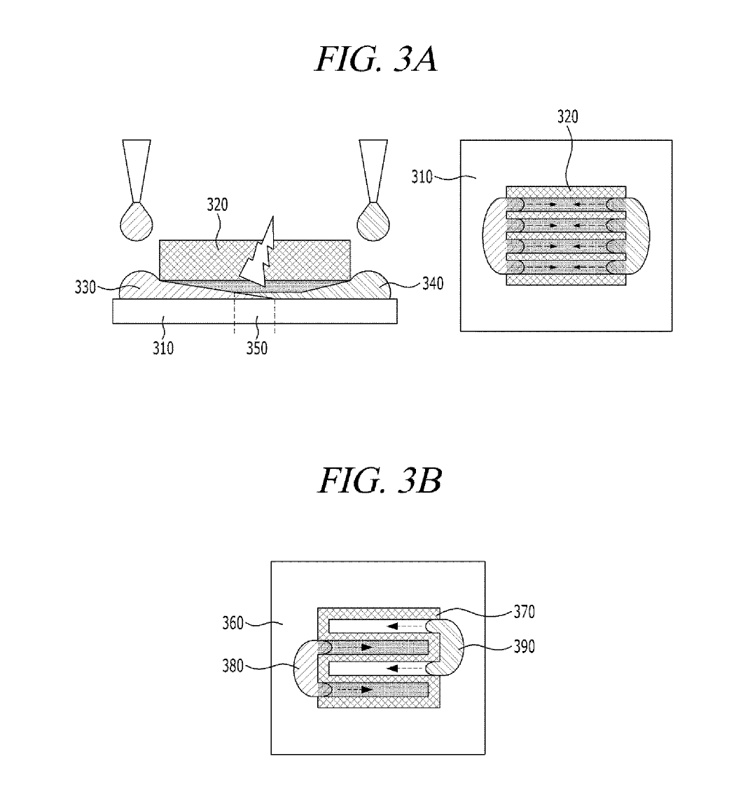

FIG. 3A and FIG. 3B are conceptual diagrams illustrating a process for forming a pattern of an organic thin film semiconductor element according to yet another exemplary embodiment of the present disclosure. As illustrated in FIG. 3A, a mold structure 320 having a groove may be positioned on an upper part of a substrate 310 to enable the groove and a top surface of the substrate 310 to form a pipe. Further, organic semiconductor materials 330 and 340 of different kinds are supplied in sequence to a surface of the substrate 310 with a predetermined time interval. For example, the organic semiconductor materials 330 and 340 of different kinds may include an N-type semiconductor material and a P-type semiconductor material, respectively.

The mold structure 320 according to an exemplary embodiment of the present disclosure is formed to have an opening for introducing the organic semiconductor materials 330 and 340 on both ends as illustrated in FIG. 3A. The organic semiconductor material 330 of one kind may be supplied to a surface of the substrate 310 adjacent to one end of the mold structure 320 and introduced toward a central part of the pipe and may flow in the pipe. Further, the organic semiconductor material 340 of the other kind may be supplied to a surface of the substrate 310 adjacent to the other end of the mold structure 320 and introduced toward the central part of the pipe and may flow in the pipe. The organic semiconductor materials 330 and 340 which are supplied with a time interval and flow in the pipe formed by the mold structure 320 and the substrate 310 may be overlapped within the pipe (350). As such, by sequentially using capillary phenomenon of the organic semiconductor materials 330 and 340 of different kinds, a CMOS element, an organic light emitting transistor element, and a pattern therein can be manufactured easily and rapidly.

Further, according to another exemplary embodiment of the present disclosure, as illustrated in FIG. 3B, a mold structure 370 having grooves may be positioned on an upper part of a substrate 360 to enable the grooves and a top surface of the substrate 360 to form pipes. Further, organic semiconductor materials 380 and 390 of different kinds are supplied to a surface of the substrate 360. For example, the organic semiconductor materials 380 and 390 of different kinds may include an N-type semiconductor material and a P-type semiconductor material, respectively.

The mold structure 370 according to another exemplary embodiment of the present disclosure may include a plurality of grooves in which directions of openings for introducing the organic semiconductor materials 380 and 390 are alternately formed as illustrated in FIG. 3B. For example, the directions of the openings for introducing the organic semiconductor materials 380 and 390 may be determined depending on the kinds of the organic semiconductor materials 380 and 390. The organic semiconductor material 380 of one kind may be supplied to a surface of the substrate 360 adjacent to one end of the mold structure 370 and introduced toward a central part of a pipe and may flow in the pipe. Further, the organic semiconductor material 390 of the other kind may be supplied to a surface of the substrate 360 adjacent to the other end of the mold structure 370 and introduced toward a central part of a pipe and may flow in the pipe. For example, the organic semiconductor material 380 may be introduced from the left, and the organic semiconductor material 390 may be introduced from the right. Accordingly, a pattern formed of the organic semiconductor material 380 and a pattern formed of the organic semiconductor material 390 may be alternately arranged.

As such, by using capillary phenomenon of the organic semiconductor materials 380 and 390 of different kinds and alternately arranging the pipes in which the organic semiconductor materials 380 and 390 of different kinds are introduced and flow, an element such as a hetero-semiconductor thin film transistor and a pattern therein can be manufactured rapidly.

Further, as illustrated in FIG. 3A and FIG. 3B, by forming the mold structures 320 and 370 to have various sizes and shapes, it is possible to manufacture patterns and elements having various shapes. Further, it is possible to adjust and save an amount of the organic semiconductor material used according the structures of the mold structures 320 and 370.

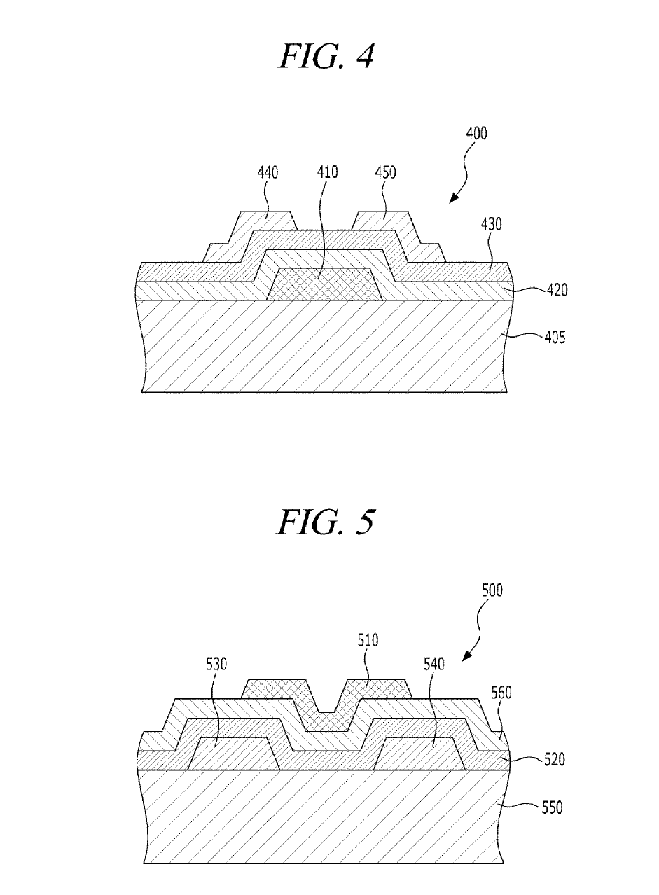

FIG. 4 is a cross-sectional view of an organic thin film transistor 400 according to an exemplary embodiment of the present disclosure. An organic thin film transistor 400 according to an exemplary embodiment of the present disclosure has a bottom gate structure in which a gate electrode 410 is formed under an organic semiconductor layer 430. As illustrated in FIG. 4, the gate electrode 410 is formed on a substrate 405, and a gate insulation layer 420 configured to cover the gate electrode 410 may be formed on the substrate 405. Further, the organic semiconductor layer 430 may be formed of an organic semiconductor material on the gate insulation layer 420. The organic semiconductor layer 430 may be applied with an electric field from the gate electrode 410. Further, a source electrode 440 and a drain electrode 450 may be formed to face each other on the organic semiconductor layer 430. Furthermore, although not illustrated, a protective layer configured to protect the organic semiconductor layer 430 may be formed on the organic semiconductor layer 430 and a passivation layer configured to cover the organic semiconductor layer 430, the source electrode 440, and the drain electrode 450 may be formed on the gate insulation layer 420.

For example, the substrate 405 may be one of a silicon substrate, a glass substrate, and a plastic substrate. Further, for example, the gate electrode 410 may be formed of a metal such as Au, Ag, Cu, Ni, Pt, Pd, Al, and Mo, or a metal alloy such as Al:Nd and Mo:W, but is not limited thereto.

Further, for example, the gate insulation layer 420 may include an insulating organic polymer. Desirably, the insulating organic polymer may include therein a double bond, a triple bond, and an aromatic ring capable of receiving charges in order to increase a capacitance of an organic insulator and minimize a leakage current. As the insulating organic polymer, any fluorine-based polymer containing fluorine may be used. For example, polymers such as a material called Cytop, polytetrafluoroethylene, a tetrafluoroethylene/perfluoro(alkyl vinyl ether) copolymer, a tetrafluoroethylene/hexa fluoropropylene copolymer, perfluorophenylene, perfluorobiphenylene, perfluoronaphthanylene, ethylene-tetrafluoroethylene, and poly(vinylidene fluoride) may be used. A hydrophobic insulation layer can be formed using a mixture of a fluorine-based polymer and a general insulating organic polymer.

As the organic semiconductor material constituting the organic semiconductor layer 430, any organic semiconductor material may be used as long as it enables formation of a thin film through a solution process. The organic semiconductor layer 430 may be formed on an upper part of the gate insulation layer 420. The organic semiconductor layer 430 may be formed by the method for forming a pattern of an organic thin film semiconductor element of the present disclosure described above with reference to FIG. 1A to FIG. 3B. Therefore, redundant explanation about a method for forming the organic semiconductor layer 430 will be omitted.

Further, for example, the source electrode 440 and the drain electrode 450 may be formed of Al, Mo and a metal alloy, such as Al:Nd and MoW, formed of two or more metals in addition to Au, Pd, Pt, Ni, Rh, Ru, Ir, and Os. As a metal oxide, ITO, IZO, NiO, Ag₂O, In₂O₃—Ag₂O, CuAlO₂, SrCu₂O₂, and Zr-doped ZnO may be used, but is not limited thereto. A combination of two or more of the above-described metals or metal oxides may also be used.

FIG. 5 is a cross-sectional view of an organic thin film transistor 500 according to another exemplary embodiment of the present disclosure. An organic thin film transistor 500 according to another exemplary embodiment of the present disclosure has a top gate structure in which a gate electrode 510 is formed on an organic semiconductor layer 520, a source electrode 530, and a drain electrode 540. As illustrated in FIG. 5, the source electrode 530 and the drain electrode 540 may be formed to face each other on an upper part of a substrate 550. Further, the organic semiconductor layer 520 in contact with the source electrode 530 and the drain electrode 540 may be formed on the upper part of the substrate 550. Furthermore, a gate insulation layer 560 may be formed on an upper part of the organic semiconductor layer 520.

The characteristics, materials, and forming methods of the respective layers and electrodes of the organic thin film transistor 500 are the same as the characteristics, materials, and forming methods of the respective layers and electrodes of the organic thin film transistor 400 described with reference to FIG. 4, and, thus, detailed explanation thereof will be omitted.

The above-described organic thin film transistors 400 and 500 can be applied as switching elements or driving elements in various electronic elements. The electronic elements may include, for example, a liquid crystal display device, an organic light emitting display device, an electrophoretic display device, and an organic sensor.

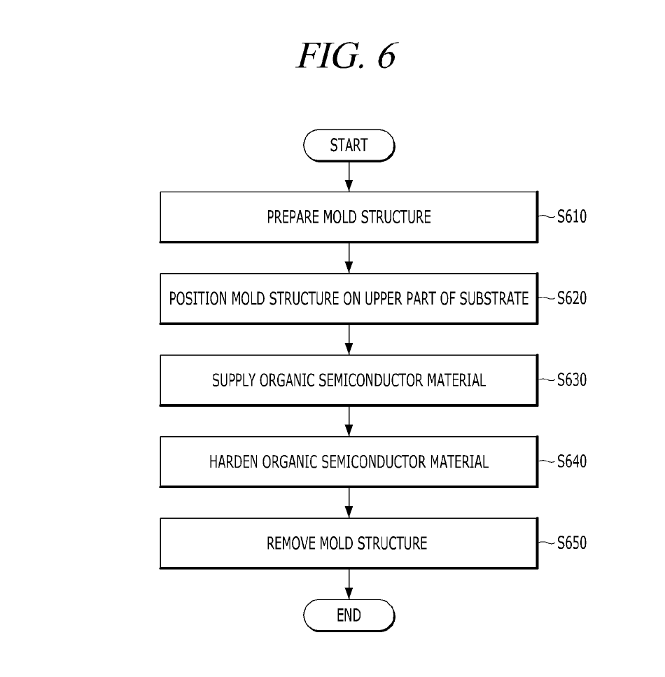

FIG. 6 is a flowchart showing a method for forming a pattern of an organic thin film semiconductor element according to an exemplary embodiment of the present disclosure. A method for forming a pattern of an organic thin film semiconductor element according to the exemplary embodiment illustrated in FIG. 6 includes the steps sequentially performed during the process for forming a pattern of an organic thin film semiconductor element as described with reference to FIG. 1A to FIG. 5. Therefore, although omitted hereinafter, the descriptions with reference to FIG. 1A to FIG. 5 may also be applied to the method for forming a pattern of an organic thin film semiconductor element according to the exemplary embodiment illustrated in FIG. 6.

Referring to FIG. 6, in S610, a mold structure having one or more grooves is prepared. The mold structure may be formed by a general mold manufacturing process. Further, the groove may have a width and a height in the range of from several tens of nanometers (nm) to several micrometers (μm).

In S620, a mold structure may be positioned on an upper part of a substrate. The mold structure is positioned on a top surface of the substrate to enable the groove of the mold structure and the substrate to form a pipe (passage). For example, the mold structure may be bonded to the top surface of the substrate to allow a bottom surface of the groove of the mold structure to face the top surface of the substrate.

In S630, an organic semiconductor material may be supplied to a surface of the substrate. The supplied organic semiconductor material may be introduced into the pipe formed by the groove of the mold structure and the substrate and may flow on the top surface of the substrate through the pipe.

In S640, the organic semiconductor material flowing in the pipe may be hardened. For example, the organic semiconductor material may be hardened by natural drying or annealing. In this way, a liquid (solvent) component included in the organic semiconductor material evaporates. Since the organic semiconductor material is hardened, the organic semiconductor material present within the pipe may be formed as a pattern of the organic thin film semiconductor element along a shape of the pipe.

In S650, after the organic semiconductor material is hardened and the pattern is formed, the mold structure may be removed.

In the above description, S610 to S650 may be further divided into additional steps or combined into fewer steps according to an exemplary embodiment of the present disclosure. Further, some steps may be skipped if necessary, or the sequence of the steps may be modified.

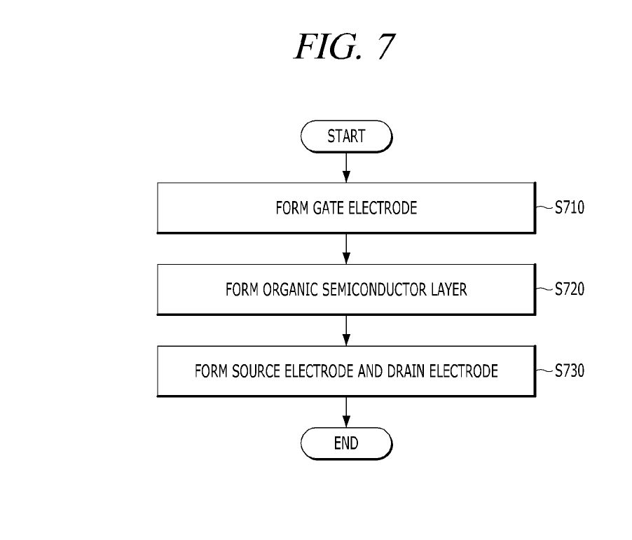

FIG. 7 is a flowchart showing a method for manufacturing an organic thin film transistor according to an exemplary embodiment of the present disclosure. A method for manufacturing an organic thin film transistor according to the exemplary embodiment illustrated in FIG. 7 includes the steps sequentially performed during the process for forming a pattern of an organic thin film semiconductor element and the process for manufacturing an organic thin film transistor as described with reference to FIG. 1A to FIG. 5. Therefore, although omitted hereinafter, the descriptions with reference to FIG. 1A to FIG. 5 may also be applied to the method for manufacturing an organic thin film transistor according to the exemplary embodiment illustrated in FIG. 7.

Referring to FIG. 7, in S710, a gate electrode may be formed on a substrate, and a gate insulation layer configured to cover the gate electrode may be formed on the gate electrode. For example, the gate insulation layer may be formed by a PECVD (plasma enhanced chemical vapor deposition) method. Further, in S710, after the gate insulation layer is formed, a wet cleaning process for removing impurities present on a top surface of the gate insulation layer may be performed. In the wet cleaning process, at least any one of IPA (isopropyl alcohol), deionized water, and acetone may be used as a cleaning solution.

In S720, an organic semiconductor layer may be formed on an upper part of the gate electrode. The organic semiconductor layer may be formed by the method for forming a pattern of an organic thin film semiconductor element described above with reference to FIG. 6. For example, a mold structure having one or more grooves may be prepared, and the mold structure may be positioned on a top surface of a substrate to enable the groove of the mold structure and the substrate to form a pipe (passage), and an organic semiconductor material may be supplied to a surface of the substrate. The supplied organic semiconductor material may be introduced into the pipe formed by the groove of the mold structure and the substrate and may flow on the top surface of the substrate through the pipe and then may be formed as a pattern of the organic thin film transistor through a hardening process.

In S730, a source electrode and a drain electrode electrically connected with the organic semiconductor layer may be formed. For example, the source electrode and the drain electrode may be formed by forming a metal layer and then patterning the metal layer with a mask by a wet or dry etching method.

In the above description, S710 to S730 may be further divided into additional steps or combined into fewer steps according to an exemplary embodiment of the present disclosure. Further, some steps may be skipped if necessary, or the sequence of the steps may be modified.

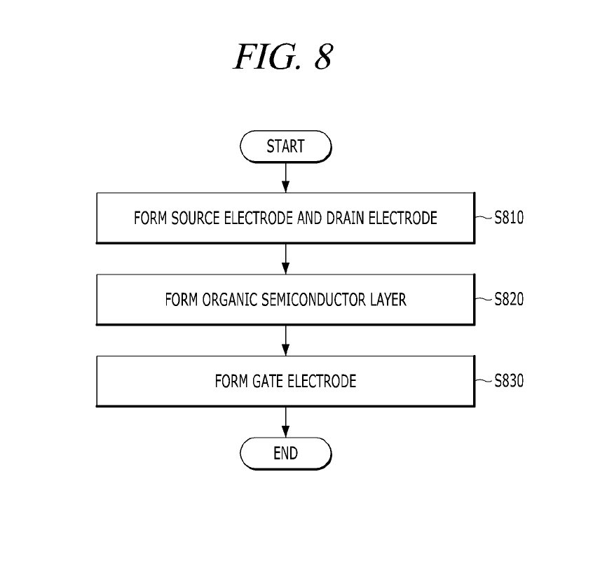

FIG. 8 is a flowchart showing a method for manufacturing an organic thin film transistor according to another exemplary embodiment of the present disclosure. A method for manufacturing an organic thin film transistor according to the exemplary embodiment illustrated in FIG. 8 includes the steps sequentially performed during the process for forming a pattern of an organic thin film semiconductor element and the process for manufacturing an organic thin film transistor as described with reference to FIG. 1A to FIG. 5. Therefore, although omitted hereinafter, the descriptions with reference to FIG. 1A to FIG. 5 may also be applied to the method for manufacturing an organic thin film transistor according to the exemplary embodiment illustrated in FIG. 8.

Referring to FIG. 8, in S810, a source electrode and a drain electrode may be formed on a substrate. For example, the source electrode and the drain electrode may be formed by forming a metal layer and then patterning the metal layer with a mask by a wet or dry etching method.

Further, in S820, an organic semiconductor layer may be formed to be in contact with the source electrode and the drain electrode. The organic semiconductor layer may be formed by the method for forming a pattern of an organic thin film semiconductor element described above with reference to FIG. 6.

Then, in S830, a gate electrode and a gate insulation layer may be formed on upper parts of the organic semiconductor layer, the source electrode, and the drain electrode.

In the above description, S810 to S830 may be further divided into additional steps or combined into fewer steps according to an exemplary embodiment of the present disclosure. Further, some steps may be skipped if necessary, or the sequence of the steps may be modified.

The above description of the present disclosure is provided for the purpose of illustration, and it would be understood by those skilled in the art that various changes and modifications may be made without changing technical conception and essential features of the present disclosure. Thus, it is clear that the above-described embodiments are illustrative in all aspects and do not limit the present disclosure. For example, each component described to be of a single type can be implemented in a distributed manner. Likewise, components described to be distributed can be implemented in a combined manner.

The scope of the present disclosure is defined by the following claims rather than by the detailed description of the embodiment. It shall be understood that all modifications and embodiments conceived from the meaning and scope of the claims and their equivalents are included in the scope of the present disclosure.

We claim:

1. A method for forming a pattern of an organic thin film semiconductor element, comprising:
preparing a mold structure having a groove;
positioning the mold structure on an upper part of a substrate to enable the groove and the substrate to form a pipe;
supplying an organic semiconductor material to a surface of the substrate; and
hardening the organic semiconductor material,
wherein the organic semiconductor material flows in the pipe formed by the groove of the mold structure and the substrate.

2. The method of claim 1,
wherein the organic semiconductor material includes a material which enables formation of a thin film through a solution process.

3. The method of claim 1, further comprising:
performing an ultraviolet ozone (UVO) treatment or oxygen plasma treatment to the surface of the substrate in contact with the organic semiconductor material supplied thereto.

4. The method of claim 1,
wherein when the organic semiconductor material is supplied to the surface of the substrate, a height formed by the organic semiconductor material is greater than a height of the pipe.

5. The method of claim 1,
wherein the hardening the organic semiconductor material includes an annealing process.

6. A method for manufacturing an organic thin film transistor, comprising:
forming a gate electrode on a substrate;
forming an organic semiconductor layer on an upper part of the gate electrode; and
forming a source electrode and a drain electrode electrically connected with the organic semiconductor layer,
wherein the forming an organic semiconductor layer includes:
preparing a mold structure having a groove;
positioning the mold structure on an upper part of the substrate to enable the groove and the substrate to form a pipe;
supplying an organic semiconductor material to the substrate; and
hardening the organic semiconductor material,
wherein the organic semiconductor material flows in the pipe formed by the groove of the mold structure and the substrate.

7. The method of claim 6,
wherein the organic semiconductor material includes a material which enables formation of a thin film through a solution process.

8. The method of claim 6,
wherein the hardening the organic semiconductor material includes an annealing process.

9. A method for manufacturing an organic thin film transistor, comprising:
forming a source electrode and a drain electrode on a substrate;
forming an organic semiconductor layer to be in contact with the source electrode and the drain electrode; and
forming a gate electrode on upper parts of the organic semiconductor layer, the source electrode, and the drain electrode,
wherein the forming an organic semiconductor layer includes:
preparing a mold structure having a groove;
positioning the mold structure on an upper part of the substrate to enable the groove and the substrate to form a pipe;
supplying an organic semiconductor material to the substrate; and
hardening the organic semiconductor material,
wherein the organic semiconductor material flows in the pipe formed by the groove of the mold structure and the substrate.

10. The method of claim 9,
wherein the organic semiconductor material includes a material which enables formation of a thin film through a solution process.

11. The method of claim 9,
wherein the hardening the organic semiconductor material includes an annealing process.

12. An organic thin film transistor comprising:
an organic semiconductor layer formed of an organic semiconductor material;
a source electrode and a drain electrode positioned to be in contact with the organic semiconductor layer and to face each other;
a gate electrode configured to apply an electric field to the organic semiconductor layer; and
a gate insulation layer positioned between the gate electrode and the organic semiconductor layer,
wherein the organic semiconductor layer is formed by the method for forming a pattern of an organic thin film semiconductor element of claim 1.

13. An organic thin film transistor comprising:
a gate electrode;
an organic semiconductor layer formed on an upper part of the gate electrode; and
a source electrode and a drain electrode electrically connected with the organic semiconductor layer,
wherein the organic semiconductor layer is formed by the method for forming a pattern of an organic thin film semiconductor element of claim 1.
